(19) United States
(12) Patent Application Publication
(10) Pub. No.: US 2025/0194329 A1
(43) Pub. Date: Jun. 12, 2025

(54) MICRO-LED CHIPLETS

(71) Applicant: Tectus Corporation, Cupertino, CA (US)

(72) Inventors: Paul Scott Martin, Palo Alto, CA (US); Michael West Wiemer, San Jose, CA (US)

(21) Appl. No.: 18/981,025

(22) Filed: Dec. 13, 2024

Related U.S. Application Data
(63) Continuation of application No. PCT/US2024/058576, filed on Dec. 5, 2024.
(60) Provisional application No. 63/606,937, filed on Dec. 6, 2023.

(51) Int. Cl. H10H 29/80; H10H 20/825; H10H 29/24

(52) U.S. Cl. CPC H10H 29/8321; H10H 20/825; H10H 29/24

(57) ABSTRACT

Chiplets containing micro-LEDs are designed with two sets of interconnects. One set connects the cathode and anode terminals on the micro-LEDs to contacts for the chiplet. These contacts may then be connected to circuitry outside the chiplet. The other set connects micro-LED terminals to test pads on the wafer when the chiplets are still in wafer form. Multiple chiplets are connected to individual test pads. The micro-LEDs may be fabricated as an array on the wafer, with the test pads arranged around the periphery of the array. As a result, automated test equipment may probe the test pads to test the chiplets while they are still in wafer form.

### CROSS-REFERENCE TO RELATED APPLICATION(S)

This application is a continuation of International Application No. PCT/US24/58576, “Micro-LED Chiplets,” filed Dec. 5, 2024; which claims priority to U.S. Provisional Patent Application Ser. No. 63/606,937, “Sparse Micro-LED Pixel Arrays,” filed Dec. 6, 2023. The subject matter of all of the foregoing is incorporated herein by reference in its entirety.

### BACKGROUND

### 1. Technical Field

This disclosure relates to micro-LED chiplets for use in displays.

### 2. Description of Related Art

Displays are an important part of modern society. They are used in a wide range of devices such as smartphones, tablets, laptops, digital signage, and augmented reality and virtual reality devices. They are also used for many different applications, including entertainment, communication, education, and work. Displays can provide high-quality visual information, and they come in different sizes, resolutions, and formats to address different needs and preferences.

In particular, there is high demand for bright and efficient displays that use micro-LEDs. In some displays, the micro-LEDs are arranged on larger pixel pitches with space between the micro-LEDs. The micro-LEDs may be fabricated as large, dense arrays of devices on wafers and then separated into chiplets. Red color chiplets are then transferred to a display substrate to form a sparse array for the red component of the display. Green and blue color chiplets are also transferred to the display substrate to form the green and blue components.

### BRIEF DESCRIPTION OF THE DRAWINGS

Embodiments of the disclosure have other advantages and features which will be more readily apparent from the following detailed description and the appended claims, when taken in conjunction with the examples in the accompanying drawings, in which:

FIGS. 1A, 1B and 1C are a plan view, a side view and a cross-sectional view of a micro-LED chiplet.

FIG. 2A is a plan view of chiplets in wafer form, showing local interconnects.

FIG. 2B is the plan view of FIG. 2A further showing wafer-level interconnects when the chiplets are in wafer form.

FIG. 3 shows a plan view of the chiplets from FIG. 2B after singulation.

FIG. 4 is a plan view from a wafer showing the connection of chiplets to test pads.

FIGS. 5A-5E show partial fabrication of chiplets.

FIG. 6 is a plan view of a hexagonal chiplet.

FIGS. 7A and 7B are plan views of chiplets in wafer form and placed on a display, respectively.

FIG. 8 is a schematic, plan view of a display using a sparse array of micro-LED chiplets.

FIGS. 9A-9C are schematic cross-sectional diagrams of chiplets in a display.

FIG. 10 shows the creation of a sparse array of chiplets via pick-and-place.

FIG. 11A-11C show steps for connecting an original chiplet and a repair chiplet to a display substrate.

### DETAILED DESCRIPTION OF THE PREFERRED EMBODIMENTS

The figures and the following description relate to preferred embodiments by way of illustration only. It should be noted that from the following discussion, alternative embodiments of the structures and methods disclosed herein will be readily recognized as viable alternatives that may be employed without departing from the principles of what is claimed.

The cost of semiconductor devices depends in large part on the number of devices that can be fabricated on a single wafer. If more devices can be fabricated on a wafer, the area per device goes down and the price per device also goes down. As a result, it is desirable to fabricate wafers with dense arrays of micro-LEDs, even if the micro-LEDs will be more widely spaced in the final display. In addition, a color pixel for a display contains different color subpixels. Red, green and blue subpixels are a common configuration for displays. If the micro-LEDs for the different color subpixels can be fabricated together on a single wafer, rather than fabricating different wafers for each color, this can also reduce the cost of the display. Once fabricated, the wafer is singulated into chiplets containing small groups of micro-LEDs. For example, a single chiplet may contain the micro-LEDs for the red, green and blue subpixels of a color pixel. Such chiplets may be referred to as white chiplets. The white chiplets are then arranged as needed for a display.

For sparse displays, the chiplets may have a much larger spacing compared to the spacing on the wafer. A sparse display made from an array of white micro-LED chiplets can provide superior performance (efficiency, brightness) at greatly reduced cost compared to existing displays. Micro-LEDs may be 50 um or smaller in size. Micro-LEDs may be as much as ten times brighter than other display technologies so a factor of ten reduction in chiplet emissive area may be achieved. Transferring white chiplets to a sparse display reduces the cost of transfer by a factor of three compared to transferring red, green and blue chiplets separately. Together, these cost savings make micro-LEDs an attractive technology for next-generation phones, tablets, televisions, automobile displays and billboards.

It is also desirable to test the chiplets while they are still in wafer form, before separating them into individual chiplets. After the wafer is singulated, the good chiplets may be transferred to a display and the bad chiplets may be discarded. However, it is impractical to provide a separate set of test pads for each chiplet or, even more impractical, for each micro-LED because test pads can be many times larger than chiplets. If separate test pads were provided, they would occupy a large area on the wafer, driving up the cost of the devices.

In one approach, micro-LED chiplets are designed with two sets of interconnects. One set connects the cathode and anode terminals on the micro-LEDs to contacts located on the sides of the chiplet. These side-contacts may then be connected to other circuitry outside the chiplet. These interconnects are contained within the chiplet and will be referred to as local interconnects.

The other interconnects connect micro-LED terminals to test pads on the wafer when the chiplets are still in wafer form. Multiple chiplets are connected to individual test pads. The micro-LEDs may be fabricated as an array on the wafer, with the test pads arranged around the periphery of the array. As a result, automated test equipment may probe the test pads to test the chiplets while they are still in wafer form. If the testing is for dead devices, many chiplets and micro-LEDs may be connected to a single test pad and all tested together. Because these interconnects connect to multiple chiplets and to the test pads, they will be referred to as wafer-level interconnects (although they are not required to run the full length of the wafer). These interconnects are severed when the wafer is singulated into individual chiplets.

In some designs, the two sets of interconnects may include different materials. The local interconnects within the chiplet may be copper because that is a fairly universal process. The wafer-level interconnects or, at least the segments between chiplets, may be aluminum. The chiplets may be separated by etching trenches between them. The use of aluminum segments, rather than copper segments, facilitate this process since aluminum is etchable whereas copper segments would not be.

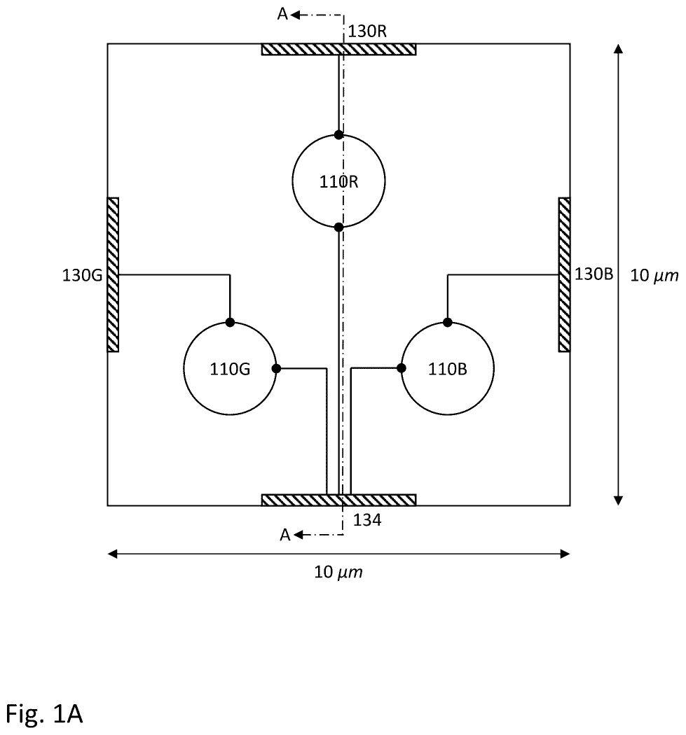

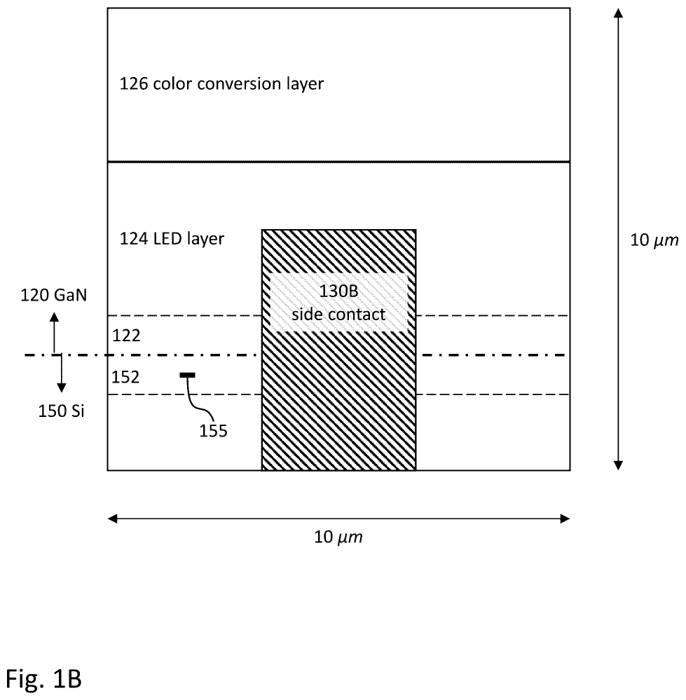

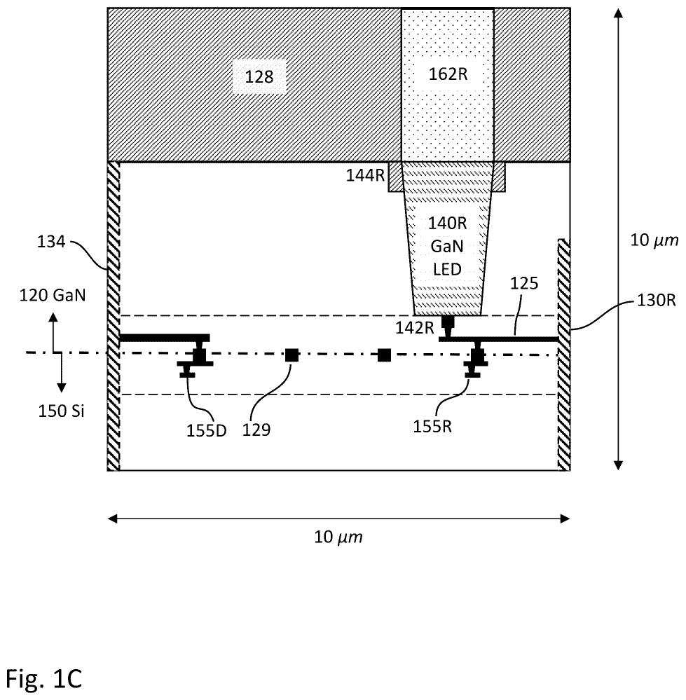

FIG. 1A is a plan view of an individual LED chiplet after singulation. In this example, the chiplet contains one color pixel with red, green and blue light emitters 110R, 110G, 110B. Each light emitter 110 includes a micro-LED that produces the light for that emitter. The chiplet also includes side-contacts 130,134, which provide external connections to the micro-LEDs.

In this example, the contacts 130,134 are side-contacts because the chiplet is small in size. In this example, the chiplet is 10 um (microns) on a side. Larger chiplets may be 50-100 um on a side. Even at those larger sizes, side-contacts can significantly reduce the area per chiplet. The side-contacts are formed on the vertical sides of the chiplet. When a chiplet is mounted on the display substrate, the sides of the chiplet are perpendicular to the substrate. The use of side-contacts enables small chiplets. It also allows different techniques for placing chiplets onto a display substrate, as discussed in more detail below.

In FIG. 1A, the side-contacts 130, 134 are shown as inset into the edge of the chiplet, but they could also protrude from the edge. In one approach, trenches are etched to form the chiplet sides. Side-contacts may be formed by metal vias that partially fill the trenches. When the wafer is thinned, the chiplets are separated as the thickness of the wafer is reduced to the depth of the trenches. This singulation process produces a kerf that is much narrower than those produced by sawing or other more conventional methods. The kerf is the material between chiplets, which is wasted material.

Micro-LEDs are devices with two terminals. The terminals are shown in FIG. 1A as the black dots on each circle 110. Connections to the terminals are shown as solid lines connecting to the black dots. These lines are schematic and do not represent the actual physical layout of the interconnects. In the example of FIG. 1A, one terminal (the control terminal) of each light emitter 110R,G,B is connected to a corresponding separate contact 130R,G,B in order to allow individual control of that micro-LED. For example, these contacts 130R,G,B may be connected to individually addressable driver circuits in the display. The other terminals (the common terminals) may all be connected to a single contact 134. For example, this contact 134 may be connected to ground. Contacts 130R,G,B may be referred to as driver contacts and contact 134 as the common contact.

FIG. 1B shows a side view of the chiplet of FIG. 1A, looking at side-contact 130B from right to left. The chiplet includes a gallium nitride (GaN) substrate 120 bonded to a silicon (Si) substrate 150. The chiplet may be roughly divided into different layers. The GaN substrate 120 includes an LED layer 124 and an interconnect layer 122. As will be discussed in FIG. 1C, the LED layer 124 contains the micro-LEDs, and interconnect layer 122 includes the local interconnects within the chiplet connecting the control terminals of the micro-LEDs to the corresponding driver contacts. In other designs, the local interconnects may be located in layers other than those in the GaN substrate.

An additional layer 126 is on top of the LED layer 124. This contains color conversion material, such as quantum dots, to convert light from the micro-LEDs to the desired color. In this example, the micro-LEDs all produce blue light. Quantum dots convert this to red and green colors for the red and green light emitters 110R,G.

The driver side-contact 130B in FIG. 1B extends from the silicon substrate 150 into the LED layer 124 but stops short of the layer 126 above. The common side-contact 134 extends to and makes connection to layer 126, as explained in more detail in FIG. 1C.

The silicon substrate 150 also includes an interconnect layer 152, which includes the wafer-level interconnects 155 or segments of these interconnects. When the chiplets were still in wafer form, these interconnects connected the control terminals from multiple chiplets to individual test pads on the wafer. When the wafer is singulated into individual chiplets, these interconnects 155 are severed between chiplets. FIG. 1B shows the severed end of one of these interconnects. The opposite end is still connected to the control terminal, but the severed end of the interconnect is electrically dangling since the interconnect no longer connects to anything on the severed end. These interconnects may be aluminum to facilitate etching trenches between chiplets to separate the chiplets. The exposed ends will then oxidize to aluminum oxide, providing a natural insulative cap to the interconnect. This process may be accelerated by using a UV ozone process. Substrates other than silicon may also be used.

FIG. 1C shows a cross-sectional view through A-A of FIG. 1A, looking from right to left. This view shows the red light emitter, which includes a blue color micro-LED 140R and quantum dots 162R that convert the blue light to red light. The micro-LED 140R includes control terminal 142R and common terminal 144R. The local interconnects 125 within the chiplet connect control terminal 142R to the corresponding driver contact 130R. The common terminal 144R is connected to the common contact 134 through aluminum 128 on the top layer. The aluminum layer 128 is deposited to make connection to the common terminal 144R and common contact 134. Containers for the quantum dots are formed in aluminum layer 128, and these are then filled with the appropriate color conversion material 162R.

Wafer-level interconnects 155R,D are also shown in the cross-section of FIG. 1C. Wafer-level interconnect 155R connects the control terminal 142R to a test pad on the wafer. The connection may include segments of the local interconnects 125 and/or may make connection through the contact 130R. Wafer-level interconnect 155D connects the common terminal 144R to the corresponding test pad. Segments of the interconnects 155R,D which are later etched to separate the chiplets are aluminum, because copper does not etch. An alternative for aluminum is tungsten. In this example, the etched interconnects are on the silicon substrate 150 but they could also be on the GaN substrate or both. FIG. 1C also shows a regular array of copper plugs 129 that fuse during hybrid bonding of the GaN and silicon substrates.

Micro-LEDs are small in size compared to other LEDs. Chiplets using micro-LEDs will also be small. For example, the micro-LEDs may be 20 um or less on a side, the chiplets may be 50 um or less on a side, and the test pads may be the same size or larger than the chiplets.

The chiplet shown in the examples of FIGS. 1A-1C may have an area not larger than 30 um×30 um, or not larger than 20 um×20 um, or even not larger than 10 um×10 um as shown in the figures. It may have a height of at least 10 um. For example, the thickness of the quantum dot layer 126 may be about 2 um, the thickness of the GaN substrate (layers 122 and 124) about 2 um, and the thickness of the silicon substate 150 about 6 um. With these dimensions, the chiplet would have a height:width aspect ratio of at least 1:3. The individual color emitters may also be small, with tall aspect ratio. They may have a height:width aspect ratio of at least 1:1.

Sawing or other conventional dicing approaches result in a kerf that is a significant fraction of the chiplet area. A singulation process based on etching trenches can produce a kerf of 1 um or less, which is more suitable for this size chiplet.

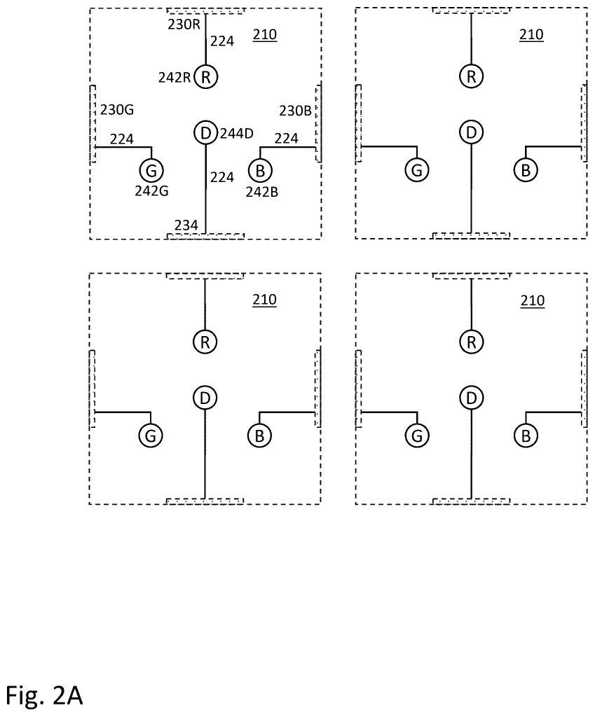

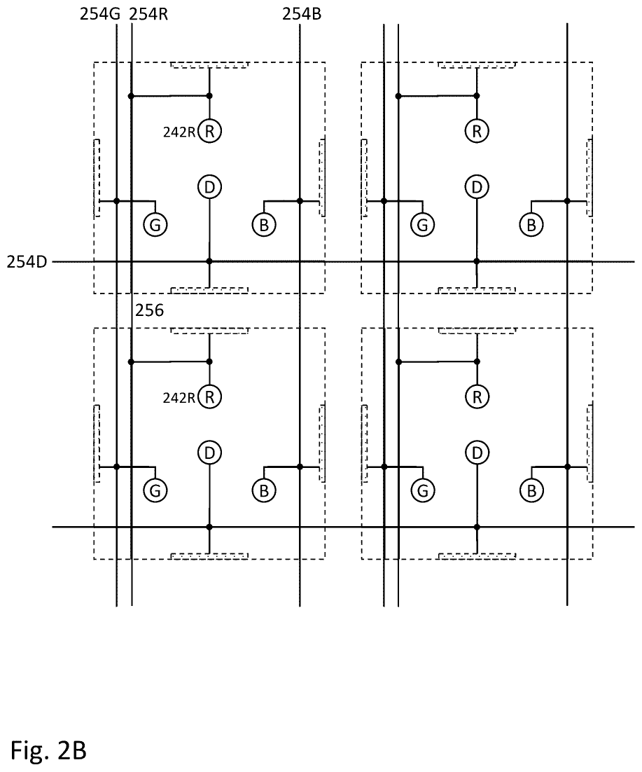

FIG. 2A is a plan view of a section of chiplets in wafer form. FIG. 2A also shows a schematic of the local interconnects within the chiplets. FIG. 2A shows a 2×2 section of chiplets 210. In FIG. 2A, 242R,G,B represent the control terminals for three micro-LEDs, and 244D represents the common terminals for the micro-LEDs. Each control terminal 242R,G,B is connected by local interconnects 224 to corresponding driver contacts 230R,G,B. The common terminals 244D are connected by local interconnects 224 to the common contact 234. The local interconnects 224 are contained within each chiplet. They may be copper since they are contained within the chiplet and are not etched later in the processing.

The contacts 230R,G,B, 234 are shown in FIG. 2A as dashed lines because they may not be formed yet and there may not be any physical structure corresponding to the dashed line at this point in the processing. Similarly, the borders of the chiplets 210 are also shown as dashed lines. These chiplets have not yet been separated into individual chiplets.

FIG. 2B is the plan view of FIG. 2A further showing wafer-level interconnects 254. In this example, the wafer-level interconnects 254R connect the control terminals 242R for one column of chiplets to a single test pad. Similarly, interconnects 254G,B connect control terminals 242G,B for one column of chiplets to a single test pad. The interconnects 254D connect the common terminals 242D for one row of chiplets to a single test pad. Because the interconnects 254 connect multiple chiplets, they include segments 256 that cross the kerf region between chiplets.

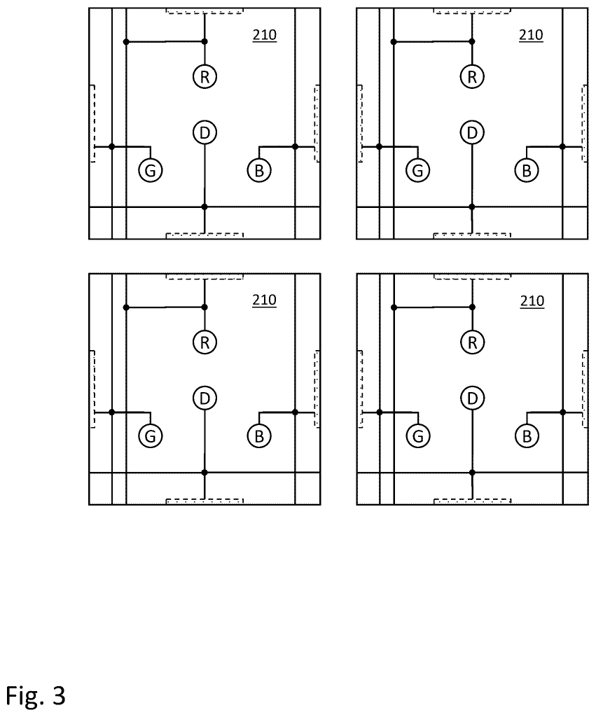

FIG. 3 shows the plan view of the chiplets of FIG. 2B after singulation. There are four chiplets 210 which have been separated from each other. The wafer-level interconnects have been severed between chiplets in the singulation process. If singulation is based on etching trenches between chiplets, then these segments (256 in FIG. 2B) of the wafer-level interconnects may be aluminum because aluminum may be etched. Singulation may produce electrically dangling segments of the wafer-level interconnects. These segments used to connect from one chiplet through the kerf region to the next chiplet, but now they are severed at the edge of the chiplet and do not connect to the next chiplet.

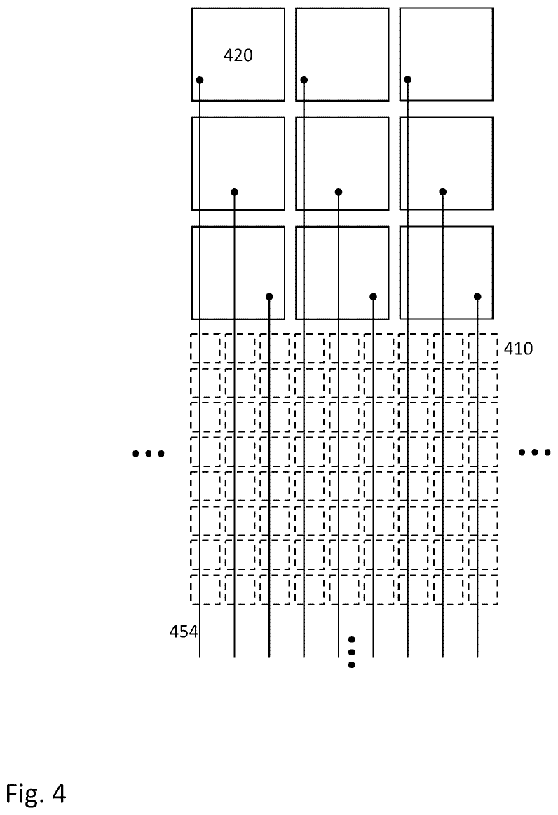

FIG. 4 is a plan view from a wafer showing the connection of chiplets to test pads. FIG. 4 shows a section from the edge of the wafer, showing nine columns from the array of chiplets 410. The lines show the wafer-level interconnects 454. The large squares are the test pads 420, which are arranged around a periphery of the chiplet array. The small dashed squares are the chiplets 410. The array may represent one reticle. In this example, each column of chiplets 410 is connected to one test pad 420. The connections to test pads are shown by black dots but, for clarity, the black dots are omitted for the connections to chiplets. Referring to FIG. 2B, this arrangement may be used to connect the control terminals 242R (or G or B) or the common terminals 244 to the corresponding test pads. The test pads 420 may be at least two times wider (four times the area) than the chiplets 410. For example, the test pads may be approximately 50-100 um wide, while the chiplets are 10-30 um wide. In FIG. 4, they are three times wider.

Because multiple chiplets are connected to one test pad, the total area of the test pads may be five percent (5%) or less of the total area of the chiplet array, even though the test pads are larger than the chiplets. For example, the chiplets may be arranged in a 1000×1000 array on a 25 um pitch. The test pads may be arranged on a 75 um pitch. If each test pad is connected to one column or row of chiplets, then 4,000 test pads are needed to handle R, G, B and common terminals. In this arrangement, the area of the test pads is less than 4% of the area of the chiplet array.

In the example of FIGS. 2B and 4, the control terminals for one column of one color of light emitter are connected to one test pad, but different color light emitters are connected to different test pads. Other arrangements are possible. For example, all of the control terminals R,G,B from a chiplet may be connected to one test pad. This allows testing of all of the micro-LEDs in a chiplet through one test pad. If all micro-LEDs are good, then the chiplet will produce white light. If not, then some other color light or no light will be produced. As another variation, the connection to a test pad may not be for one row/column. It could be for multiple rows/columns or for partial rows/columns. Test pads along the top (bottom) edge of the array may be used to test micro-LEDs in the top (bottom) half of the array, in which case test pads will be connected to half-rows/columns. Test pads may also be arranged along the right and left edges of the array.

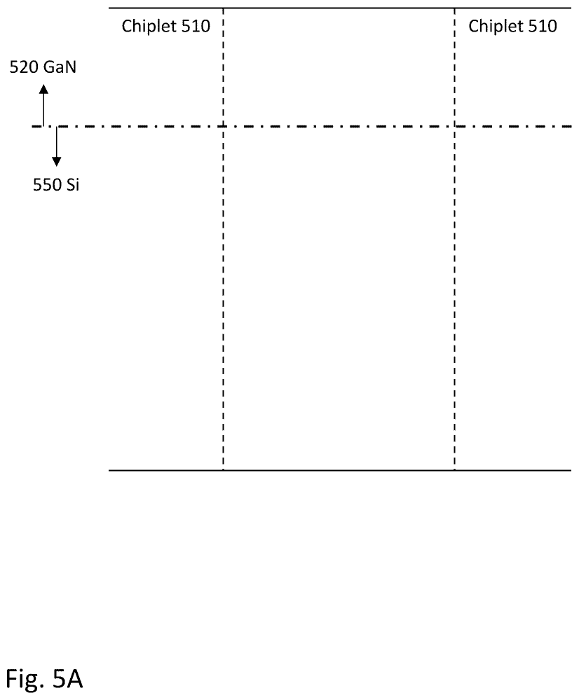

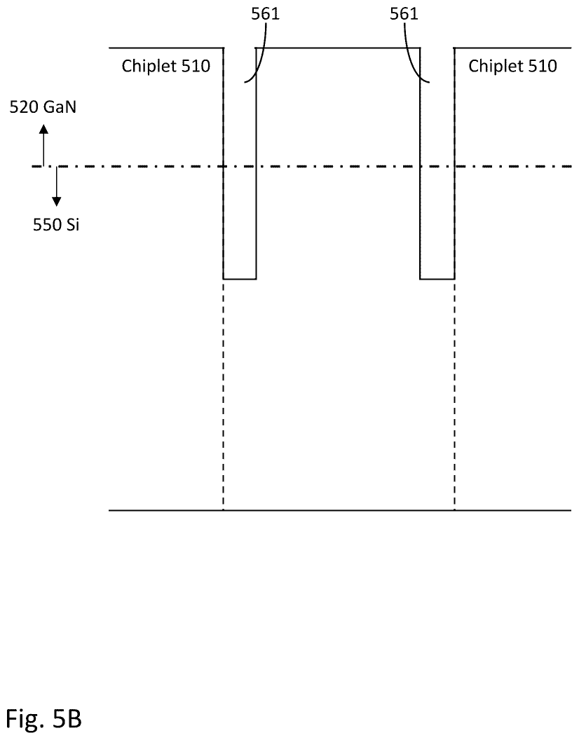

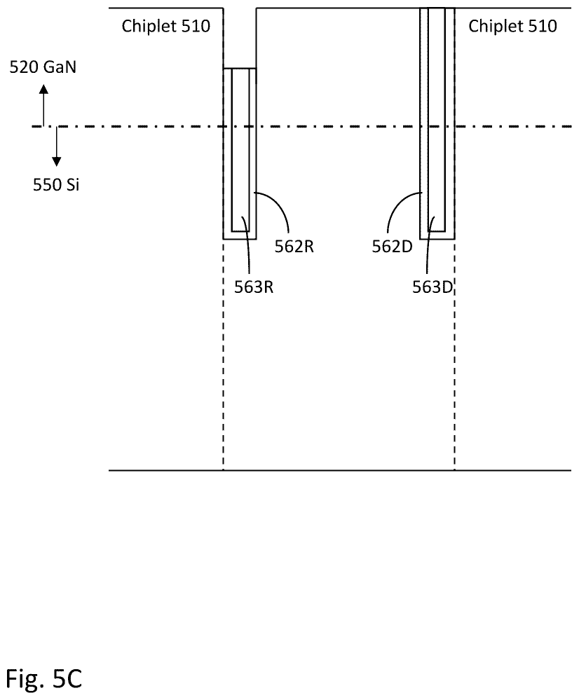

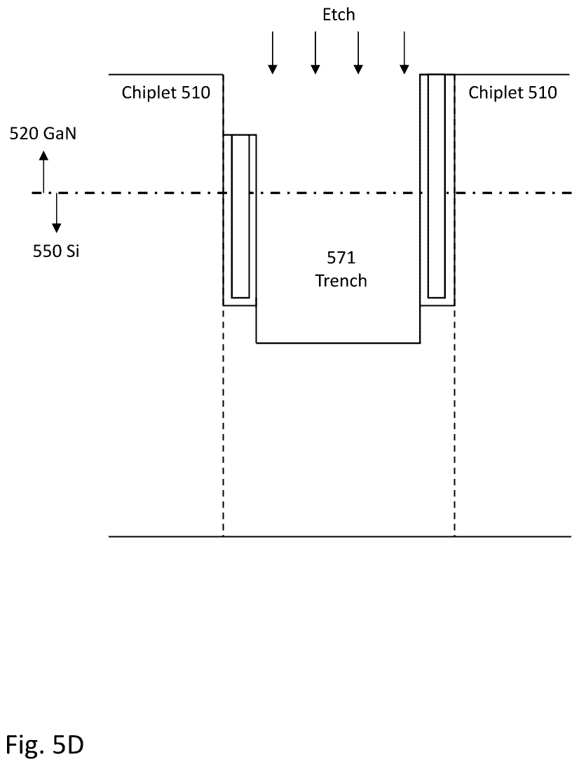

FIGS. 5A-5E show partial fabrication of chiplets. FIGS. 5A-5E are not to scale. FIG. 5A shows two adjacent chiplets 510 still in wafer form. The dashed vertical lines are the boundaries of each chiplet 510. The area between the two boundaries will be removed to separate the two chiplets. In FIG. 5A, the micro-LEDs and interconnects have already been fabricated. The wafer includes a GaN substrate 520 (including aluminum/color conversion layer) on top of a silicon substrate 550. In one process, a few microns of GaN are grown on a silicon carrier substrate (not substrate 550 in FIG. 5A). This GaN will become the GaN substrate 520 shown in FIG. 5A. Interconnects are formed on the GaN substrate 520 while supported by the carrier. Separately, interconnects are also formed in a different silicon substrate 550. The GaN substrate 520 is hybrid bonded to the silicon substrate 550. The carrier for the GaN substrate may then be removed. The micro-LEDs, top aluminum layer, quantum dot containers and quantum dots are formed on the GaN substrate, yielding the structure shown in FIG. 5A. The wafer in this form may be tested to determine which chiplets are good.

FIGS. 5B-5C show fabrication of the side-contacts. As shown in FIG. 5B, trenches 561 are etched through the GaN 520 between chiplets, extending into the silicon 550. The trenches are etched only along the chiplet edges where side-contacts are to be formed and not around the entire chiplet. The trenches are coated, for example with TaN/Ta/TaN/Cu or TaN/Cu layers 562 as shown in FIG. 5C. This may be deposited by sputtering. The layers are thin. The TaN may be 20-200 nm and the copper Cu 5-20 nm. Copper 563 is plated into the trenches, forming the side-contacts. On the right side of FIG. 5C, the side-contact 562D/563D makes contact with the top aluminum layer of the right chiplet 510, such as side-contact 134 in FIG. 1C. On the left side of FIG. 5C, the side-contact 562R/563R does not make contact with the top aluminum layer, such as side-contact 130R in FIG. 1C.

FIGS. 5D-5E show singulation. In FIG. 5D, trenches 571 are etched from the GaN 520 side into the kerf region between chiplets. These trenches extend into the silicon 550 and also extend around the entire boundary of the chiplet. In FIG. 5E, the wafer is attached to dicing tape on the GaN side and is then thinned from the silicon 550 side. This may be mechanical grinding, for example. When the thinning 572 reaches the trench 571, the chiplets 510 are separated from the rest of the wafer. This can produce kerf regions of 1 um width or less, thus reducing wasted material given the small size of the chiplets.

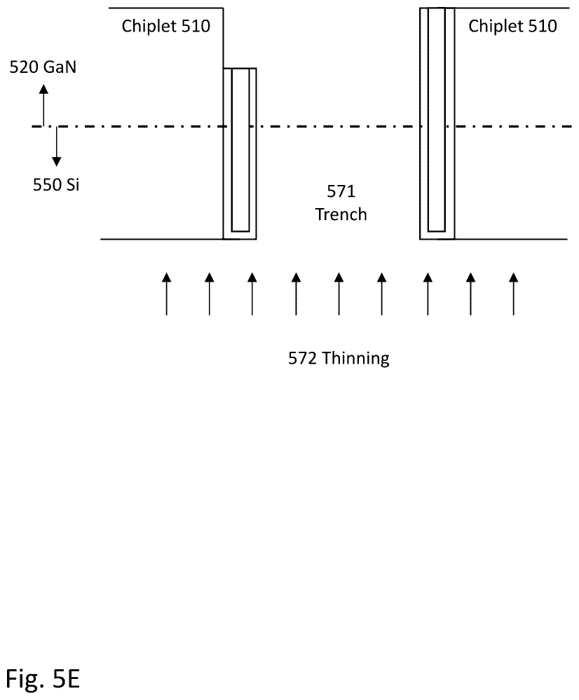

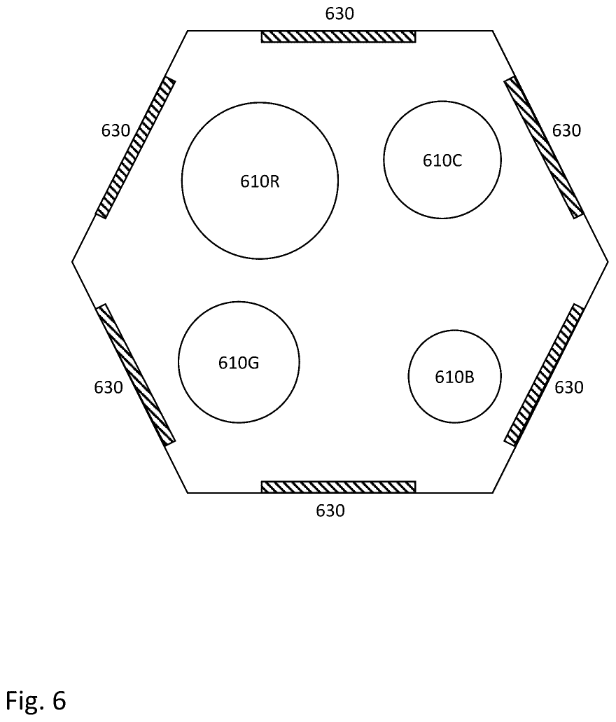

Chiplets may have footprints with shapes other than squares and rectangles. FIG. 6 is a plan view of a chiplet with a hexagonal footprint. Hexagonal designs offer more sides on which to make side-contacts, which may be useful if there are more than three subpixels per chiplet. Here there are four colors of subpixels: red 610R, green 610G, blue 610B, and cyan 610C. FIG. 6 shows six side-contacts 630. Four of these are driver contacts that connect to the control terminals of the four subpixels. One is a common contact that connects to the common terminals of the subpixels. The sixth side-contact may be used for some other purpose. Like chiplets with square or rectangular footprints, six-sided chiplets may be densely packed on a wafer.

A sparse array of micro-LED chiplets may be constructed by singulating an already tested wafer into individual chiplets and then placing known good chiplets on a display substrate at desired locations. The display substrate may contain conductive traces to connect electrical signals for the chiplet of each pixel. For each pixel, both normal and repair conductive traces may be provided. Repair traces and pads provide an opportunity to correct any display defects caused by inoperative chiplets. Sparse, micro-LED chiplet arrays may be formed on planar or curved, opaque or transparent substrates, or any combination of those.

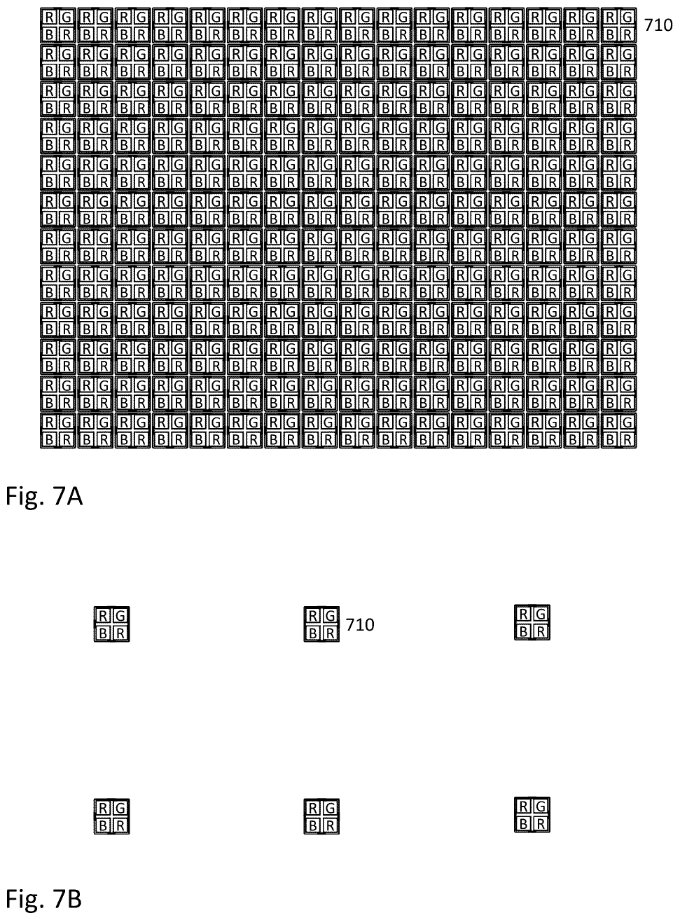

FIGS. 7A and 7B are plan views of chiplets in wafer form and placed on a display, respectively. In these figures, each chiplet 710 includes a white color pixel with red, green and blue subpixels. The red subpixel includes two red (R) light emitters. The green and blue subpixels include one green (G) and one blue (B) light emitter, respectively. FIG. 7A shows an array of chiplets in wafer form, as described above. These chiplets may be tested while still in wafer form. They are densely packed in order to reduce cost. The chiplets are fabricated with minimal gap between neighbors. The pitch of the chiplets in the array is only slightly larger than the chiplet width. Millions of chiplets may be formed on a single semiconductor wafer.

Chiplets 710 may be spaced much farther apart when they are positioned on a display, as shown in FIG. 7B. The chiplet-to-chiplet spacing may be 100× or more than the size of the chiplets. Micro-LEDs are bright, so a small area chiplet may provide enough light for one pixel in a sparse display. Since wafer area is a primary factor in display cost, the ability to space out the chiplets, yet maintain adequate brightness, enables cost efficient displays. In some displays, the chiplets occupy less than 1% of an area of the display.

Table 1 below compares the areas of a chiplet using side-contacts and one using a conventional micro-LED layout. In a conventional layout, contacts are placed on the top or bottom and they must be large enough for connection to other circuitry on the display. Placing vertical electrical contacts on the sides of the chiplet, rather than using horizontal contacts on the top or bottom, greatly reduces the area of each chiplet. In addition, a singulation process based on thinning a wafer until an etched trench is reached, results in a much thinner kerf than mechanical or laser dicing. These two effects reduce the area of each chiplet on a wafer so that many more chiplets may be fabricated on each wafer.

TABLE 1
Area comparison of different chiplets

| Device | Area of chiplet | Kerf width | Total area |
|---|---|---|---|
| side-contact | 10 um × 10 um = | 1 um | 11 um × 11 um = |
| micro-LED + | 100 um² | | 121 um² |
| etch | | | |
| singulation | | | |
| conventional | 20 um × 40 um = | 10 um | 30 um × 50 um = |
| micro-LED + | 800 um² | | 1500 um² |
| mechanical | | | |
| dicing | | | |

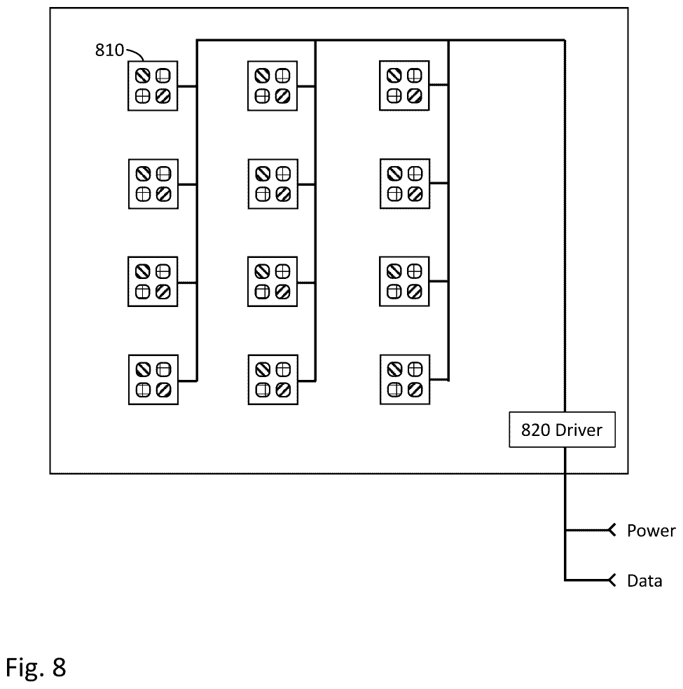

FIG. 8 is a schematic plan view of a display using a sparse array of micro-LED chiplets. FIG. 8 is not drawn to scale. For clarity, FIG. 8 shows only twelve white chiplets 810. An actual display may have hundreds of thousands or even several million chiplets. Each chiplet is connected to a drive signal(s). An incoming data stream, representing which chiplets to illuminate with color and brightness information for each, arrives at a display driver chip 820. This chip (or chips) may store and process calibration data, ambient light and temperature data, timing functions, and color and brightness information, among others.

The driver chip 820 sends drive currents to each chiplet and to each color subpixel. Various addressing or demultiplexing techniques may be used. The driver may use analog or digital control to vary the current. For example, pulse width modulation and/or pulse amplitude modulation may be used. The external driver chip 820 receives data representing a color and brightness to be generated by the chiplet. Depending on the wavelengths of the red, green and blue emitters of the chiplet, a large fraction of a standard color gamut may be covered. In FIG. 8, each chiplet has a ground and three signal lines, one each for red, green and blue, but the individual signal lines are not shown in the figure.

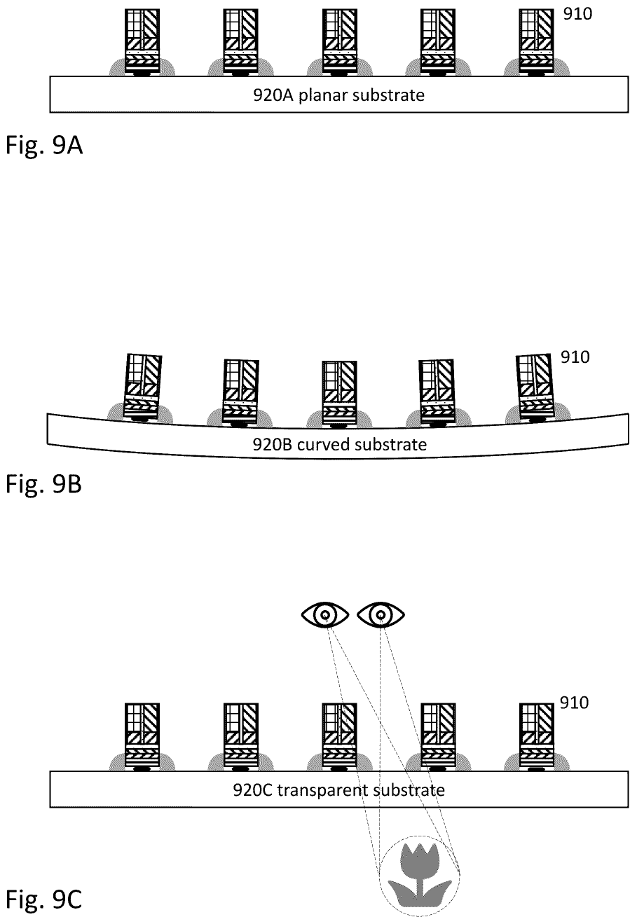

FIGS. 9A-9C are schematic cross-sectional diagrams of chiplets in a display. In these figures, the chiplets 910 are placed in a sparse array on a substrate 920A-C. Placement of the chiplets on a grooved, a planar or other type of substrate may be accomplished with a pick-and-place machine. Each chiplet may be secured by adhesive between the bottom of the chiplet and the substrate. However, electrical connections are made to the sides of the chiplet, not to the bottom. A sparse array of chiplets may be formed on a planar substrate or a curved (or otherwise non-planar) substrate. Furthermore, the substrate may be opaque or transparent to light. If the substrate is transparent, then a see-through display may be formed. Such a display allows a viewer to see digital images appearing superimposed on a natural background. In FIG. 9A the substrate 920A is planar; in FIG. 9B the substrate 920B is curved; and in FIG. 9C the substrate 920C is transparent.

The arrays of chiplets in FIG. 9 may differ from conventional designs in several respects. First, the adhesive securing the chiplet to the substrate may provide a thermal path that is independent of the electrical connections between chiplet and substrate. In conventional designs, these electrical connections also provide a thermal path from the chiplet to the substrate. Second, these electrical connections may be copper. Due to the ductility of copper, and the placement of the connections on the sides of the chiplets, such connections can withstand tension on curved or flexible substrates. In conventional designs, soldered connections on the bottom of a chiplet are placed in shear stress (and may not be able to withstand that stress) during bending. Third, the side-contacts do not block light emitted by the chiplets and therefore may be formed by opaque metals. In conventional designs, top contacts may be made from transparent conductors which necessarily attenuate light somewhat.

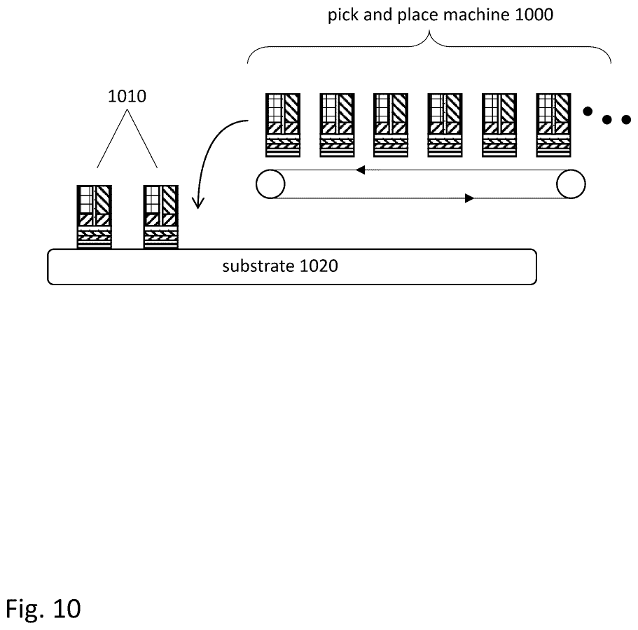

FIG. 10 shows the creation of a sparse array of chiplets via pick-and-place. A pick and place machine 1000 transfers chiplets 1010 to substrate 1020. Alternative techniques for mass transfer, including self-assembly and laser release mechanisms, may also be used. The result of the transfer process is chiplets arranged on a display at much larger spacing compared to their spacing when manufactured on a wafer. If chiplets are manufactured on a wafer at 10 um pitch, but placed on a display substrate at 100 um pitch, then 1 unit of wafer area supplies chiplets for 100 units of display area, for example.

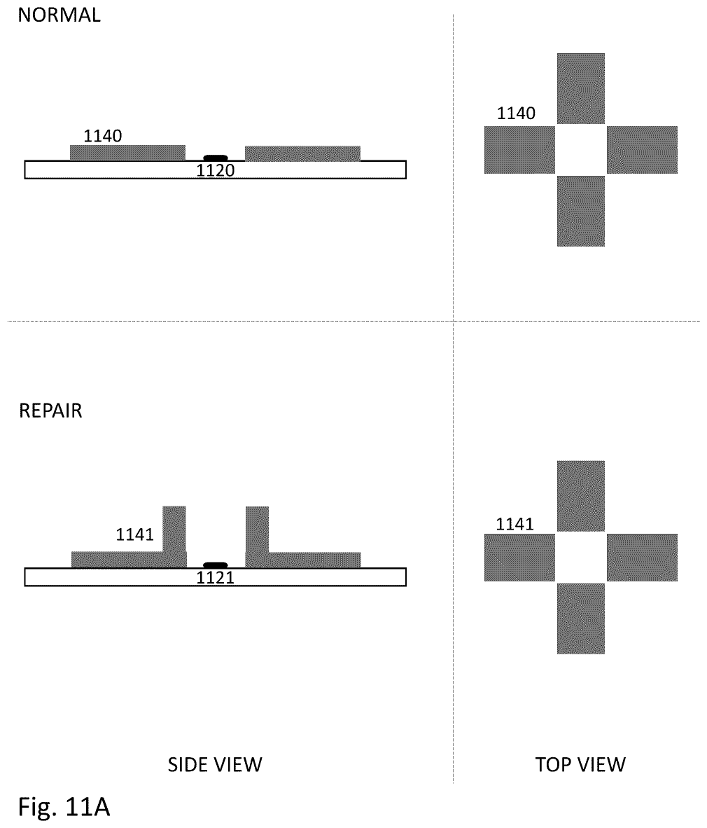

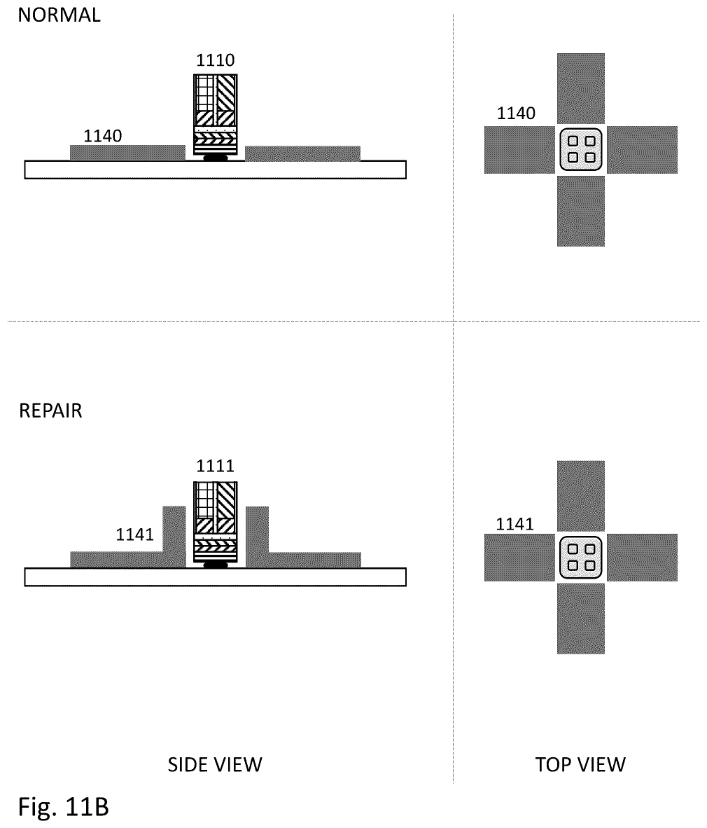

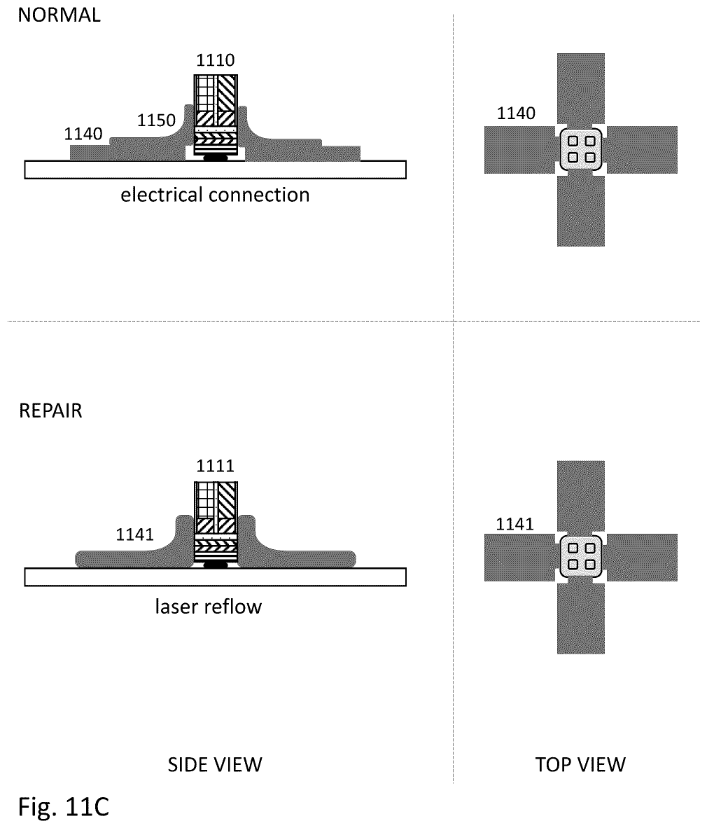

FIG. 11A-11C show steps for connecting a chiplet 1110, 1111 to circuitry on a display substrate 1120, 1121. The top half of these figures, labeled “NORMAL,” illustrates steps involved in placing and connecting a chiplet with side-contacts to a display substrate during the original assembly of the display. Inevitably, a few such chiplets in a display do not work properly. If 99.99% of the chiplets in a 4K standard resolution (8.3 million chiplets) display work properly, then 830 chiplets may need to be repaired. The lower half of each figure, labeled “REPAIR,” illustrates steps involved in placing and connecting a repair chiplet to a display substrate. Repair chiplets are placed near non-working chiplets in a display. The left column of each figure shows a side view of the chiplet placement site, while the right column shows a top view of the same site.

FIG. 11A shows pads 1140, 1141 where original and repair chiplets are connected to a sparse micro-LED display. In this example, each chiplet connects to four pads 1140, 1141 on the substrate. These may correspond to connections for the three driver contacts and one common contact, as described in FIGS. 1-2.

FIG. 11B shows side and top views of the normal and repair situations, after chiplet placement but before electrical connection. The chiplets 1110, 1111 may be connected to the substrate mechanically, e.g. with adhesive, but this is not required. If a thermally conductive adhesive affixes the chiplet to the substrate, then the thermal and electrical connections between the chiplet and the substrate are separated.

The thickness of bond traces 1141, 1140 near the chiplet is much greater in the case of the repair chiplet 1111 than in the case of the original chiplet 1110. In one example, the bond traces are 1 um thick for the original chiplets 1110 and 4 um thick for repair chiplets 1111.

FIG. 11C shows side and top views of normal and repair situations, after chiplet placement and electric connection. Original chiplets 1110 are connected via conductive material 1150 that forms a fillet between the side-contact of the chiplet and the contact pad 1140 of the display. If a thermally conductive adhesive affixes the chiplet to the substrate, then the electrically conductive fillet need not also provide a thermal path to the substrate.

Repair chiplets 1111 may be connected by laser melting the thick bond trace 1141 adjacent to the chiplet. When a display is first manufactured, bond traces may be laid out for original and repair chiplets. However, repair chiplets need only be placed and connected at sites where the original chiplet fails to operate properly. Forming an electrical connection to a repair chiplet by melting a thick bond trace via laser reflow permits repairs to be made quickly at defect sites. Furthermore the laser may be used to cut traces connected to a failed original chiplet to prevent any part of it from lighting up.

Sparse micro-LED displays may be optimized for various market segments. They are applicable to display specifications from VGA to 8K and beyond. The high brightness of micro-LEDs enables manufacturing efficiency and cost savings by spreading chiplets out over much greater areas when in use compared to when they are manufactured.

Although the detailed description contains many specifics, these should not be construed as limiting the scope of the invention but merely as illustrating different examples. It should be appreciated that the scope of the disclosure includes other embodiments not discussed in detail above. Various other modifications, changes and variations which will be apparent to those skilled in the art may be made in the arrangement, operation and details of the method and apparatus disclosed herein without departing from the spirit and scope as defined in the appended claims. Therefore, the scope of the invention should be determined by the appended claims and their legal equivalents.

What is claimed is:

1. A wafer comprising:
an array of chiplets, each chiplet comprising a color pixel with at least two different color subpixels, the chiplet further comprising:
two or more micro-LEDs that generate light for the different color subpixels, each micro-LED having a control terminal and a common terminal;
two or more driver side-contacts suitable for electrical connection to driver circuits in a display once the wafer is singulated into individual chiplets; and
local interconnects within the chiplet connecting the control terminals to the driver side-contacts;
test pads suitable for probing by automated test equipment; and
wafer-level interconnects that connect control terminals from multiple chiplets to individual test pads when the chiplets are still in wafer form.

2. The wafer of claim 1, wherein all the control terminals in one chiplet are connected to one test pad.

3. The wafer of claim 1, wherein the micro-LEDs for different color subpixels generate a same color light, and the color subpixels further comprise color conversion material.

4. The wafer of claim 1, wherein the test pads are arranged around a periphery of the array of chiplets.

5. The wafer of claim 1, wherein the local interconnects comprise copper interconnects, and the wafer-level interconnects comprise aluminum interconnects.

6. The wafer of claim 1, further comprising:
a gallium nitride (GaN) substrate that includes the micro-LEDs, the driver side-contacts, the local interconnects, and the test pads; and
a second substrate attached to the GaN substrate, the second substrate including at least some segments of the wafer-level interconnects.

7. The wafer of claim 6, wherein the segments of the wafer-level interconnects in the second substrate are aluminum interconnects.

8. The wafer of claim 6, wherein the second substrate is a silicon (Si) substrate and the wafer further comprises copper plugs that hybrid bond the GaN substrate with the Si substrate.

9. The wafer of claim 1, wherein an area of one test pad is at least four times larger than an area of one singulated chiplet.

10. The wafer of claim 1, wherein a total area of the test pads is not more than 5% of a total area of the array of chiplets.

11. A color pixel chiplet comprising:
two or more micro-LEDs that generate light for different color subpixels of the color pixel, each micro-LED having a control terminal and a common terminal;
driver side-contacts suitable for electrical connection to driver circuits in a display;
local interconnects connecting the control terminals to the driver side-contacts; and
segments of wafer-level interconnects, wherein the segments are electrically dangling at an edge of the chiplet.

12. The chiplet of claim 11 wherein the segments connect on one end to the control terminals.

13. The chiplet of claim 11, wherein each micro-LED has a separate driver side-contact.

14. The chiplet of claim 11, further comprising: a common side-contact connected to all of the common terminals.

15. The chiplet of claim 14, further comprising: an aluminum layer connecting the common terminals to the common side-contact, wherein the aluminum layer and the local interconnects are on opposite sides of the micro-LEDs.

16. The chiplet of claim 15, further comprising: containers formed in the aluminum layer, the containers containing color conversion material.

17. The chiplet of claim 11, wherein the micro-LEDs generate light for different color subpixels, and the subpixels have a height:width aspect ratio of at least 1:1.

18. The chiplet of claim 17, further comprising: color conversion quantum dots placed in close proximity to the micro-LEDs.

19. The chiplet of claim 17, wherein the micro-LEDs emit blue light and the chiplet further comprises: quantum dots that convert the blue light to red light or green light.

20. A display comprising:
a plurality of individually addressable color pixel chiplets arranged on a display substrate, wherein the color pixel chiplets comprise:
two or more micro-LEDs that generate light for different color subpixels of the color pixel, each micro-LED having a control terminal and a common terminal;
driver side-contacts suitable for electrical connection to driver circuits in a display;
local interconnects connecting the control terminals to the driver side-contacts; and
segments of wafer-level interconnects, wherein the segments are electrically dangling at an edge of the chiplet.

21. The display of claim 20, wherein the chiplets occupy less than 1% of an area of the display.

22. The display of claim 20, wherein mechanical connections to the display substrate are made to the bottom of each chiplet.

23. The display of claim 22, wherein the mechanical connections are formed by an adhesive.

24. The display of claim 22, wherein no electrical connection is made between the display substrate and the bottoms of the chiplets.

25. The display of claim 20, further comprising: normal and repair conductive traces for at least some of the chiplets.

26. The display of claim 25, wherein the repair conductive traces are patterned with metal thick enough to be reflowed under laser illumination during a repair procedure.
